(19) United States
(12) Patent Application Publication
(10) Pub. No.: US 2022/0415396 A1
(43) Pub. Date: Dec. 29, 2022

(54) TERNARY CONTENT ADDRESSABLE MEMORY DEVICE BASED ON TERNARY MEMORY CELL

(71) Applicant: UNIST(ULSAN NATIONAL INSTITUTE OF SCIENCE AND TECHNOLOGY), Ulsan (KR)

(72) Inventors: Kyung Rok Kim, Ulsan (KR); Jae Won Jeong, Ulsan (KR); Youngeun Choi, Ulsan (KR); Wooseok Kim, Ulsan (KR)

(73) Assignee: UNIST(ULSAN NATIONAL INSTITUTE OF SCIENCE AND TECHNOLOGY), Ulsan (KR)

(21) Appl. No.: 17/672,662

(22) Filed: Feb. 15, 2022

(30) Foreign Application Priority Data
Jun. 28, 2021 (KR) 10-2021-0084150

(51) Int. Cl. G11C 15/04; G11C 11/412; G11C 11/419

(52) U.S. Cl. CPC G11C 15/046; G11C 11/412; G11C 11/419

(57) ABSTRACT

Disclosed is a TCAM device based on a ternary memory cell. A TCAM cell includes a ternary memory cell for storing ternary data and a comparison circuit for obtaining a stored value stored in the ternary memory cell and a search value input via a search line of a search driver, identifying a data match between the stored value and the search value, and outputting a result of the identification via a match line. The comparison circuit includes a first transistor pair that receives an inverted stored value that is an inverted value of the stored value of the ternary memory cell and the search value and a second transistor pair that receives the stored value of the ternary memory cell and an inverted search value that is an inverted value of the search value. The first transistor pair and the second transistor pair are connected in parallel to each other.

### CROSS-REFERENCE TO RELATED APPLICATION

This application is based on and claims priority under 35 U.S.C. § 119 to Korean Patent Application No. 10-2021-0084150, filed on Jun. 28, 2021, in the Korean Intellectual Property Office, the disclosure of which is incorporated by reference herein in its entirety.

### BACKGROUND

### 1. Field

The disclosure relates to a ternary content addressable memory (TCAM) device based on a ternary memory cell, and more particularly, to a circuit design of a TCAM device using T-CMOS.

### 2. Description of the Related Art

Content addressable memory (CAM) devices indicate devices that support data reading, writing, and searching operations. In a search operation, a CAM device may perform a function of comparing search data with stored data. For example, for one cycle, search data may be compared with entries of data stored in a CAM device, and when each bit of a data entry matches each bit of the search data, the CAM device outputs an address of a matched data entry. Here, data of logic “0” or logic “1” may be used as a data entry of the CAM device. CAM is widely used in an application that requires very fast searches in a database, as in networking, imaging, voice recognition, and the like.

A ternary content addressable memory (TCAM) device performs a function similar to that of the CAM device. However, a data entry of a TCAM device may further store a “don't care” bit “X” in addition to a logic “0” and a logic “1”. A memory cell storing a “don't care” bit is not compared with the search data. In other words, regardless of search data, a memory cell storing a “don't care” bit always outputs a matched result.

According to the related art, the TCAM device consumes high power due to the parallel operation characteristics in the basic mechanism of search. In other words, a TCAM device according to the related art uses two memory cells to store ternary information, and thus, the area and the consumed power are increased twice or more. Furthermore, according to the related art, standby power consumption resulting from an increase in leakage current due to the improvement of complementary metal oxide semiconductor (CMOS) integration is very large. With a rapid development of intelligent loT (internet of things) and edge computing, complex and huge information is input to next-generation routers and switching devices. Accordingly, in a situation where a demand for memory address search hardware capable of an ultralow power and high performance operation is increasing, there is a demand for a circuit design technology of the TCAM device to reduce power consumption while maintaining the search performance of a current TCAM.

### SUMMARY

Provided are a ternary memory cell for calculating logic values stored in a memory cell by using a ternary logic circuit and outputting the calculated logic values, and a TCAM device including the same.

Furthermore, provided are a device and a method for increasing energy efficiency and area efficiency of a TCAM circuit design by storing information at a low current through a T-CMOS-based TCAM circuit design.

Provided are a device and a method for reducing power consumption of a TCAM device by storing information at a low current through a T-CMOS-based TCAM circuit design.

Additional aspects will be set forth in part in the description which follows and, in part, will be apparent from the description, or may be learned by practice of the presented embodiments of the disclosure.

According to an aspect of the disclosure, a ternary content addressable memory (TCAM) cell in a TCAM device based on a ternary memory cell includes a ternary memory cell configured to store ternary data, and a comparison circuit configured to obtain a stored value stored in the ternary memory cell and a search value input via a search line of a search driver, identify a data match between the stored value and the search value, and output a result of the identification via a match line, wherein the comparison circuit includes a first transistor pair that receives an inverted stored value that is an inverted value of the stored value of the ternary memory cell and the search value, and a second transistor pair that receives the stored value of the ternary memory cell and an inverted search value that is an inverted value of the search value, and the first transistor pair and the second transistor pair are connected in parallel to each other.

According to another embodiment, the first transistor pair may include a first transistor configured to receive the inverted stored value from a second node corresponding to the inverted stored value of ternary memory cell and a second transistor configured to receive a search value via a first search line of the search driver, the first transistor and the second transistor being connected in series to each other, and the second transistor pair includes a third transistor configured to receive the stored value from a first node corresponding to the stored value of the ternary memory cell and a fourth transistor configured to receive the inverted search value via a second search line of the search driver, the third transistor and the fourth transistor being connected in series to each other.

According to another embodiment, the first transistor may be connected to the second node, the match line, and the second transistor, the second transistor may be connected to the first transistor and the first search line, the third transistor may be connected to the first node, the match line, and the fourth transistor, and the fourth transistor may be connected to the third transistor and the second search line.

According to another embodiment, the first transistor pair may identify whether the inverted stored value matches the search value, the second transistor pair may identify whether the stored value matches the inverted search value, and the comparison circuit may be configured to output a signal indicating a result of a data match via the match line, on the basis of an identification result of the first transistor pair and an identification result of the second transistor pair.

According to another embodiment, the TCAM cell may include one ternary memory cell and one comparison circuit.

According to another embodiment, the number of transistors included in the comparison circuit may be four, and the number of transistors included in the TCAM cell may be ten.

According to another aspect of the disclosure, a ternary content addressable memory (TCAM) device based on a ternary memory cell includes a search driver configured to provide a search word via a search fine, a TCAM cell array in which at least one TCAM cell is arranged, the at least one TCAM cell including a ternary memory cell and a comparison circuit, wherein the comparison circuit is configured to identify a data match between a stored value stored in the ternary memory cell and a search value of a search word input via a search line, and to output a result of the identification to an encoder via a match line, and the encoder configured to output an address of the TCAM cell array having data matched with the search word, on the basis of a voltage provided via the match line connected to the TCAM cell array, wherein the comparison circuit of the TCAM cell includes a first transistor pair that receives an inverted stored value that is an inverted value of the stored value of the ternary memory cell and the search value, and a second transistor pair that receives the stored value of the ternary memory cell and an inverted search value that is an inverted value of the search value, and the first transistor pair and the second transistor pair are connected in parallel to each other.

According to another embodiment, the first transistor pair may include a first transistor configured to receive the inverted stored value from a second node corresponding to the inverted stored value of ternary memory cell and a second transistor configured to receive a search value via a first search line of the search driver, the first transistor and the second transistor being connected in series to each other, and the second transistor pair may include a third transistor configured to receive the stored value from a first node corresponding to the stored value of the ternary memory cell and a fourth transistor configured to receive the inverted search value via a second search line of the search driver, the third transistor and the fourth transistor being connected in series to each other.

According to another embodiment, the TCAM cell may include one ternary memory cell and one comparison circuit.

Various respective aspects and features of the present invention are defined in the appended claims. Combinations of the characteristics of dependent claims can be appropriately combined with the characteristics of independent claims, not just explicitly presented in the claims.

Furthermore, one or more characteristics selected from any one embodiment described in the disclosure may be combined with one or more characteristics selected from other embodiments described in the disclosure, and an alternative combination of the characteristics may at least partially reduce one or more technical problems discussed in the disclosure, or technical problems discernable by a typical technician from the disclosure, and furthermore, a particular combination or permutation of embodiment features is possible unless understood by the typical technician as being incompatible.

In any described example implementation described in the disclosure, two or more physically separate constituent elements may be alternatively integrated into a single constituent element, if the integration is possible, and when the same function is performed by the single constituent element, the integration is possible. Reversely, the single constituent element of any embodiment described in the disclosure may be alternatively implemented, if appropriate, as two or more separate constituent elements performing the same function.

The purpose of certain embodiments of the present invention is to at least partially solve, reduce, or remove at least one of problems and/or disadvantages related to the related art. Certain embodiments are to provide at least one of the advantages described below.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of a TCAM device according to various embodiments of the disclosure;

FIG. 2 is a block diagram showing a connection relationship of a TCAM device, according to various embodiments of the disclosure;

FIG. 3 is a circuit diagram of a TCAM cell in a TCAM device, according to various embodiments of the disclosure;

FIG. 4 is a block diagram of an inverter included in a ternary memory cell in a TCAM device, according to various embodiments of the disclosure; and

FIG. 5 is a graph showing an operation of an inverter included in a ternary memory cell in a TCAM device, according to various embodiments of the disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The terms used in the specification are merely used to describe particular embodiments, and are not intended to limit the disclosure. An expression used in the singular encompasses the expression of the plural, unless it has a clearly different meaning in the context. Unless otherwise defined, all terms (including technical and scientific terms) used herein have the same meaning as commonly understood by one of ordinary skill in the art to which embodiments belong. The terms as those defined in generally used dictionaries are construed to have meanings matching that in the context of related technology and, unless clearly defined otherwise, are not construed to be ideally or excessively formal. In some cases, even a term defined in the disclosure cannot be construed to exclude embodiments of the disclosure.

In various embodiments of the disclosure described below, a hardware-based approach method is described as an example. However, since various embodiments of the disclosure include technology that uses both hardware and software, various embodiments of the disclosure do not exclude software-based access methods.

Hereinafter, the disclosure relates to a TCAM device based on a ternary memory cell. In detail, the disclosure discloses a technology to increase area efficiency and reduce power consumption of TCAM devices through a T-CMOS-based TCAM circuit design in ternary memory cell-based TCAM devices.

Hereinafter, various embodiments of the disclosure will be described with reference to the accompanying drawings so that a person skilled in the art to which the disclosure belongs can easily work. However, the present embodiments may be implemented in various forms, not by being limited to the embodiments presented below. In the description of the disclosure, certain detailed explanations of related art are omitted when it is deemed that they may unnecessarily obscure the essence of the disclosure. In the drawings, similar reference numerals denote the same or similar elements in various aspects, and any redundant description thereof is omitted.

Furthermore, in the specification, when a constituent element “connects” or is “connected” to another constituent element, the constituent element contacts or is connected to the other constituent element not only directly, but also electrically through at least one of other constituent elements interposed therebetween. Also, when a part may “include” a certain constituent element, unless specified otherwise, it may not be construed to exclude another constituent element but may be construed to further include other constituent elements.

The disclosure may be described in terms of functional block components and various processing steps. Such functional blocks may be realized by any number of hardware and/or software components configured to perform the specified functions. For example, the disclosure may employ various integrated circuit components for a certain function. The functional blocks of the disclosure may be implemented with any programming or scripting language. The functional blocks of the disclosure may be implemented with an algorithm executed on one or more processors. A function performed by a functional block in the disclosure may be performed by a plurality of functional blocks, or functions performed by a plurality of functional blocks in the disclosure may be performed by one functional block. Furthermore, the disclosure may employ related-art technologies for electronic environment settings, signal processing, data processing, and/or the like.

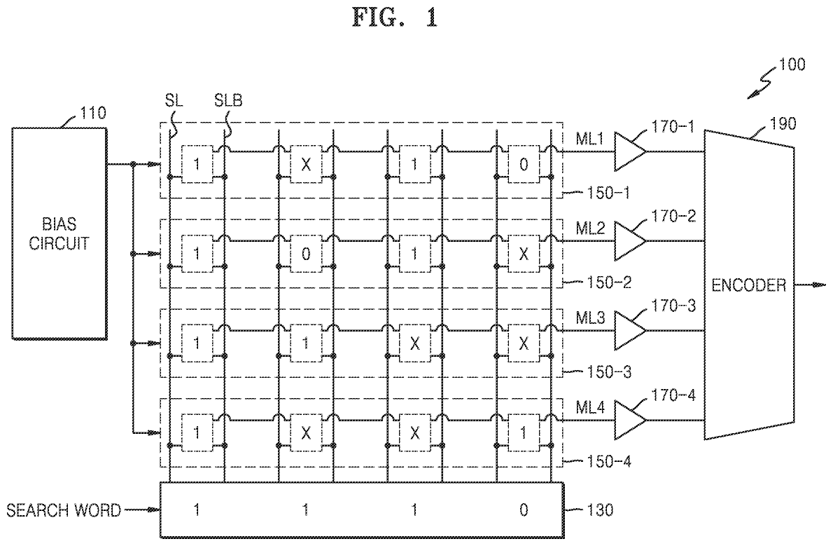

FIG. 1 is a block diagram of a TCAM device 100 according to various embodiments of the disclosure. Referring to FIG. 1, the TCAM device 100 may include a bias circuit 110, a search driver 130, first to fourth TCAM cell arrays 150-1 to 150-4, first to fourth match amplifiers 170-1 to 170-4, and an encoder 190. In FIG. 1, the number of the first to fourth TCAM cell arrays 150-1 to 150-4 and the number of the first to fourth match amplifiers 170-1 to 170-4 are merely exemplary, and the disclosure is not limited thereto.

The bias circuit 110 generates a voltage to turn on a TCAM device by using a dummy memory cell that models a memory cell. According to one embodiment of the disclosure, the bias circuit 110 may provide a generated voltage to the first to fourth TCAM cell arrays 150-1 to 150-4.

The search driver 130 performs a function of providing a code word to a TCAM cell array via a search fine pair SL and SLB. A code word may indicate data may indicate data compared with data stored in the first to fourth TCAM cell arrays 150-1 to 150-4. According to one embodiment of the disclosure, the code word may be expressed as a search word, and each bit of a search word may be indicated as a search value. Referring to FIG. 1, the search word may be indicated as “1110”.

The search driver 130 may provide a voltage corresponding to a first code “1” to a first search line pair. A voltage corresponding to a logic “1” may be provided to a first search line SL, and a voltage corresponding to a logic “0” that is complementary data to the logic “1” may be provided to a second search line SLB. In the same method, the search driver 130 may provide voltages corresponding to a second code “1” to a second search line pair, voltages corresponding to a third code “1” to a third search line pair, and voltages corresponding to a fourth code “0” to a fourth search line pair.

Each of the first to fourth TCAM cell arrays 150-1 to 150-4 may include at least one TCAM cell. According to one embodiment of the disclosure, although an example in which each of the first to fourth TCAM cell arrays 150-1 to 150-4 includes four TCAM cells is illustrated, the number of TCAM cells in FIG. 1 is a mere example, and the number of memory cells may be determined according to the various code word sizes such as 32 bits or 256 bits. Furthermore, the number of the illustrated data lines may be changed according to the size of a code word.

Each TCAM cell included in the first to fourth TCAM cell arrays 150-1 to 150-4 may store a logic “1” a logic “0”, and a “don't care” bit. When the data stored in the TCAM cell is searched for, regardless of the search word, the TCAM cell where the “don't care” bit is stored may output a result indicating that the data is matched.

Each of the TCAM cells included in the first to fourth TCAM cell arrays 150-1 to 150-4 may determine whether the stored data matches a provided search word on the bases of the voltage provided from the bias circuit 110. In this state, before a recent search operation after a precious data search operation, first to fourth match lines ML1 to ML4 connected to the first to fourth match amplifiers 170-1 to 170-4 may be pre-charged to a power voltage V_{DD}.

The first to fourth TCAM cell arrays 150-1 to 150-4 each compare the stored data with the search word. According to one embodiment of the disclosure, in the first TCAM cell array 150-1, bits of stored data “1X10” are respectively matched with bits of a search word “1110”, and thus, the first TCAM cell array 150-1 does not discharge the first match line ML1. In the same method, in the third TCAM cell array 150-3, the stored data “11XX” matches a code word “1110”, and thus, the third TCAM cell array 150-3 does not discharge the third match line ML3. In contrast, the data stored in the second TCAM cell array 150-2 and the fourth TCAM cell array 150-4 do not match the search word, the second TCAM cell array 150-2 and the fourth TCAM cell array 150-4 respectively discharge the second match line ML2 and the fourth match line ML4 to a ground voltage GND.

The first to fourth match amplifiers 170-1 to 170-4 each receive the power voltage WD that is not discharged from each of the match lines ML1 to ML4, and buffer the received voltage and output the voltage to the encoder 190. According to one embodiment of the disclosure, the first and third match amplifiers 170-1 and 170-3 respectively receive the power voltage Wo via the first and third match lines ML1 and ML3, and buffer and output the voltage to the encoder 190, and the second and fourth match amplifiers 170-2 and 170-4 respectively receive the ground voltage GND that is discharged through the second and fourth match lines ML2 and ML4, and buffer and output the voltage to the encoder 190.

The encoder 190 outputs the address of a TCAM cell array having data that matches the search word, as a match address, on the basis of the voltages provided from the first to fourth match amplifiers 170-1 to 170-4. When there are a plurality of matching TCAM cell arrays, the encoder 190 may output the address of one TCAM cell array according to a priority order algorithm. According to one embodiment of the disclosure, according to the priority order algorithm, the encoder 190 may set such that a TCAM cell array having a less number of don't care bits has a higher priority order. Referring to FIG. 1, the encoder 190 may determine the address of the first TCAM cell array 150-1 having a less number of don't care bits, as a match address, among the first TCAM cell array 150-1 and the third TCAM cell array 150-3. The encoder 190 may output a determined match address.

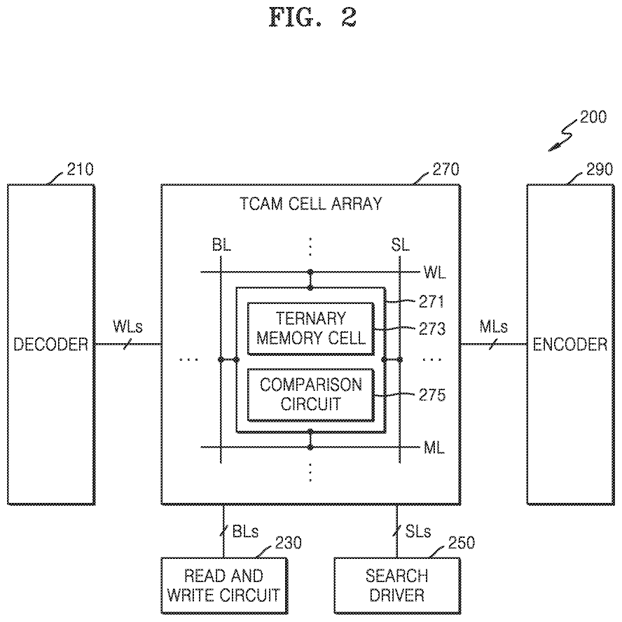

FIG. 2 is a block diagram showing a connection relationship of a TCAM device 200, according to various embodiments of the disclosure. In detail, FIG. 2 shows an example of a connection relationship of the TCAM device 200 corresponding to the TCAM device 100 of FIG. 1.

The TCAM device 200 may receive a command and an address from the outside, and receive or output data. For example, the TCAM device 200 may receive a command such as a write command or a read command and an address corresponding to the command. The TCAM device 200 may receive data in response to a write command, and output data in response to a read command. In some embodiments, a command, an address, and data may be received or transmitted through independent channels, and in some embodiments, at least two of a command, an address, and data may be received or transmitted through the same channel.

Referring to FIG. 2, a memory device may include a decoder 210, a read and write circuit 230, a search driver 250, a TCAM cell array 270, and an encoder 290.

The decoder 210 performs a function of optionally controlling a word line in response to an operation mode command generated by a memory controller. The decoder 210 may be connected to the TCAM cell array 270 via a plurality of word lines WLs. According to one embodiment of the disclosure, the decoder 210 may activate a word line when data is stored in or read out from a TCAM cell in a certain row of the TCAM cell array 270.

The read and write circuit 230 performs a function of latching write data or read data. The read and write circuit 230 may be connected to the TCAM cell array 270 via a plurality of bit lines BLs. According to one embodiment of the disclosure, the read and write circuit 230 may include a sense amplifier circuit, data input buffers, and data output buffers.

The search driver 250 may perform a function of providing the TCAM cell array 270 with a search word to search for a memory address. The search driver 250 may be connected to the TCAM cell array 270 via a plurality of search lines SLs. A search word may be input to the TCAM cell array 270 via the search lines SLs.

The TCAM cell array 270 may include at least one TCAM cell 271. According to one embodiment of the disclosure, the TCAM cell array 270 may have a structure in which at least one TCAM cell including a ternary memory cell 273 and a comparison circuit 275 is arranged. The comparison circuit 275 may identify a data match between a stored value stored in the ternary memory cell 273 and a search value of a search word input via the search lines SLs, and output an identification result via the match lines MLs. The TCAM cell 271 may have three different states, and accordingly, store ternary logic values corresponding to the three different states. In the following description, the ternary logic values to be stored in a TCAM cell may be referred to as “0,” “1,” and “2”, or collectively as “0/1/2” or simply as ternary values. The TCAM cell 271 may have a logic-in-memory (LIM) structure.

The ternary memory cell 273 may indicate a memory cell capable of storing ternary logic values. According to an embodiment of the disclosure, the ternary memory cell may indicate static random access memory (SRAM) including a ternary logic circuit or a ternary logic element. According to an embodiment of the disclosure, the ternary memory cell may be referred to as ternary SRAM or T-SRAM.

The comparison circuit 275 perform a function of comparing a search value of a search word with a stored value stored in the TCAM cell 271. According to one embodiment of the disclosure, the comparison circuit 275 may be connected to at least one search line SL of the search lines SLs connected to the search driver 250 and at least one match line ML of the match lines MLs connected to the encoder 290. The comparison circuit 275 may compare the search value of the search word received via the search line SL with the stored value stored in the TCAM cell 271, and output a comparison result via the match line ML.

The TCAM cell array 270 may be connected to the decoder 210 via the word lines WLs, and to the read and write circuit 230 via the bit lines BLs. The TCAM cell 271 may be coupled to one word line WL of the word lines WLs, and to at least one bit line BL of the bit lines BLs. The TCAM cell 271 may have a structure to store a ternary logic value provided via at least one bit line BL.

The encoder 290 may perform a function of outputting an address corresponding to currently input search data in response to a logic state of the match line ML. According to one embodiment of the disclosure, the encoder 290 may output the address of a TCAM cell array having data matched with the search word, on the basis of the voltage provided via the match line ML.

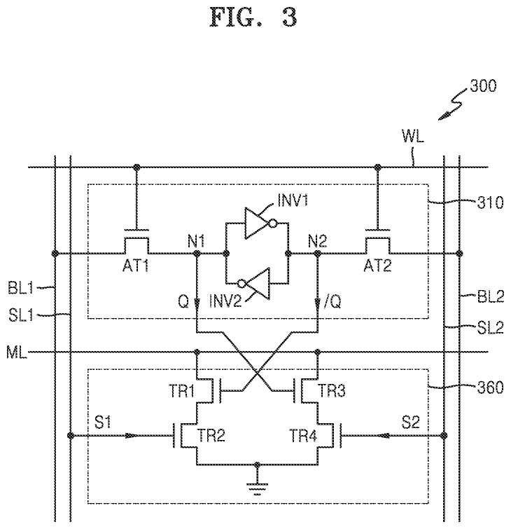

FIG. 3 is a circuit diagram of a TCAM cell 300 in a TCAM device, according to various embodiments of the disclosure. FIG. 3 shows an example of the TCAM cell 300 that corresponds to the TCAM cell 271 of FIG. 2. FIG. 3 is a circuit diagram of a new TCAM cell including a total of ten elements including four elements connected to first and second search lines SL1 and SL2 and the match line ML, in a T-CMOS-based T-SRAM (6T ternary SRAM) cell having the same are as that of a CMOS-based binary SRAM cell.

Referring to FIG. 3, the TCAM cell 300 may be connected to the word line WL, to a first bit line BL1 and a second bit line BL2 as at least one bit line BL, and to the first search line SL1 and the second search fine SL2 as at least one search line. The TCAM cell 300 may store one logic value of ternary logic values, that is, 0/1/2.

Referring to FIG. 3, the TCAM cell 300 may include a ternary memory cell 310 and a comparison circuit 360. The ternary memory cell 310 may include a first inverter INV1, a second inverter INV2, a first access transistor AT1, and a second access transistor AT2, and the comparison circuit 360 may include first to fourth transistors TR1 to TR4.

The first inverter INV1 and the second inverter INV2 may be cross-connected at a first node N1 and a second node N2, and accordingly may store one of logic values of 0/1/2. According to an embodiment of the disclosure, when the first node N1 has a positive supply voltage V_{DD} and the second node N2 has the ground voltage GND or a negative supply voltage V_{SS}, the ternary memory cell 310 may be referred to as a cell that stores a logic value 2 (Q=2). Furthermore, when each of a first node N1 and a second node N2 has an intermediate voltage, for example, V_{DD}/2 or (V_{DD}+V_{SS})/2, the ternary memory cell 310 may be referred to as one that stores a logic value 1 (Q=1). Furthermore, when the first node N1 has the ground voltage GND or the negative supply voltage V_{SS}, and the second node N2 has the positive supply voltage VD, the ternary memory cell 310 may be referred to as one that stores a logic value 0 (Q=0).

The first access transistor AT1 may be connected to the first node N1 and the first bit line BL1, and may have a gate, or a control terminal, connected to the word line WL. The first access transistor AT1 may electrically connect or disconnect the first node N1 and the first bit line BL1, according to the voltage of the word line WL. For example, the first access transistor AT1 may be an N-channel field effect transistor (NFET), and may electrically connect the first node N1 and the first bit line BL1 to each other, in response to the voltage of the word line WL that is activated, that is, at a high level. The first access transistor AT1 may electrically disconnect the first node N1 and the first bit line BL1 from each other, in response to the voltage of the word line WL that is deactivated, that is, at a low level. The second access transistor AT2 may be connected to the second node N2 and the second bit line BL2, similarly to the first access transistor AT1, and may have a gate, or a control terminal, connected to the word line WL. The first access transistor AT1 and the second access transistor AT2 are described below as being assumed to be NFETs, and the embodiments of the present disclosure may be applied to a case in which the first access transistor AT1 and the second access transistor AT2 are P-channel field effect transistors (PFETs), transmission gates, and the like.

The comparison circuit 360 may be connected to the first node N1 and the second node N2, and to the first search line SL1 and the second search line SL2. Accordingly, the comparison circuit 360 may receive a value Q (hereinafter, referred to as the stored value) stored in the ternary memory cell 310 and an inverted value /Q of the stored value, and receive a first search value S1 and a second search value S2. According to another embodiment of the disclosure, the comparison circuit 360 may receive only one of the stored value Q and the inverted value /Q of the stored value Q, or one input value or three or more input values. The comparison circuit 360 may operate two or more of the received values Q, /Q, S1, and S2 and identify whether a data stored value stored in the ternary memory cell 310 matches the search value. Then, the comparison circuit 360 may output an identification result of the stored value and the search value via the match line ML.

According to one embodiment of the disclosure, the comparison circuit 360 may have a structure in which a first transistor pair for receiving the inverted stored value that is an inverted value of the stored value of the ternary memory cell 310 and the search value, and a second transistor pair for receiving the stored value of the ternary memory cell 310 and the inverted search value that is an inverted value of the search value, are connected in parallel to each other. The first transistor pair may have a structure in which a first transistor TR1 for receiving the inverted stored value from the second node N2 corresponding to the inverted stored value of the ternary memory cell 310, and a second transistor TR2 for receiving the search value via the first search line SL of the search driver 250, are connected in series to each other. Likewise, the second transistor pair may have a structure in which a third transistor TR3 for receiving the stored value from the first node N1 and a fourth transistor TR4 for receiving the inverted search value via the second search line SL2 of the search driver 250 are connected in series to each other.

In detail, in the circuit structure of the comparison circuit 360, the first transistor TR1 may be connected to the second node N2, the match line ML, and the second transistor TR2, and the second transistor TR2 may be connected to the first transistor TR1 and the first search line SL1, and the third transistor TR3 may be connected to the first node N1, the match line ML, and the fourth transistor TR4, and the fourth transistor TR4 may be connected to the third transistor TR3 and the second search line SL2.

Accordingly, in the comparison circuit 360, the first transistor TR1 and the second transistor TR2 may identify whether the inverted stored value of the ternary memory cell 310 matches the search value, and the third transistor TR3a and the fourth transistor TR4 may identify whether the stored value matches the inverted search value. The comparison circuit 360 may identify whether the stored data matches the search data, on the basis of a comparison result, and output a match result via the match line ML. In other words, the comparison circuit 360 may output a signal indicating a result of data match, via the match line ML, on the basis of an identification result of the first transistor pair and an identification result of the second transistor pair.

The TCAM cell array including at least one TCAM cell may discharge the match line ML on the basis of the match result identified in each TCAM cell. According to one embodiment of the disclosure, the match line ML having an increased voltage through the precharge operation may keep or discharge the voltage according to the stored value and the search value. Accordingly, the TCAM cell array may perform a memory address search function. According to one embodiment of the disclosure, when the stored value matches the search value in all TCAM cells included in the TCAM cell array, the TCAM cell array does not discharge the match line ML. Reversely, when the stored value does not match the search value in at least one of the TCAM cells included in the TCAM cell array, the TCAM cell array discharges the match line ML.

According to the present disclosure, as the total number of transistors included in the ternary memory cell 310 is six and the number of transistors included in the comparison circuit 360 is four, the TCAM cell 271 may include a total of ten transistors. According to a memory device of the related art, two ternary memory cells are connected to one comparison circuit. Accordingly, the related-art memory device may include at least sixteen transistors including twelve transistors included in a ternary memory cell and four transistors included in a comparison circuit. In other words, by using sixteen transistors, the related-art memory device has low area efficiency and high power consumption. In contrast, a TCAM cell according to the disclosure may include one ternary memory cell and one comparison circuit. Accordingly, as a memory cell according to the disclosure may include a total of ten transistors, ternary information is stored based on an off-level low current, thereby providing very low standby power consumption and high area efficiency.

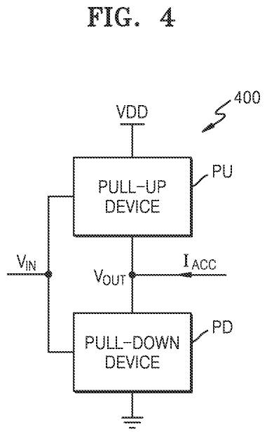

FIG. 4 is a block diagram of an inverter 400 included in a ternary memory cell in a TCAM device, according to various embodiments of the disclosure. FIG. 4 shows an example of a pair of inverters included in the ternary memory cell 310 of FIG. 3. Each inverter may include elements configured to pass a constant current therethrough during turn-off.

The inverter performs a function of generating an output voltage V_{OUT} by inverting an input voltage V_{IN}. Referring to FIG. 4, the inverter may include a pull-up device PU and a pull-down device PD that are serially connected to each other between a positive supply voltage Vo and the ground voltage GND (or a negative supply voltage V_{SS}). The pull-up device PU may be turned off in response to the input voltage V_{IN} of a high level, for example, the positive supply voltage Vo, and turned on in response to the input voltage V_{IN} of a low level, for example, the ground voltage GND. In the other hand, the pull-down device PD may be turned off in response to the input voltage V_{IN} of a low level, for example, the ground voltage GND, and turned on in response to the input voltage V_{IN} of a high level, for example, the positive supply voltage V_{IN}. Accordingly, similar to a binary logic circuit, the output voltage V_{OUT} of a low level, for example, GND may be output in response to the input voltage V_{IN} of a high level, for example, V_{DD}, and the output voltage V_{OUT} of a high level, for example, Von may be output in response to the input voltage VW of a low level, for example, GND.

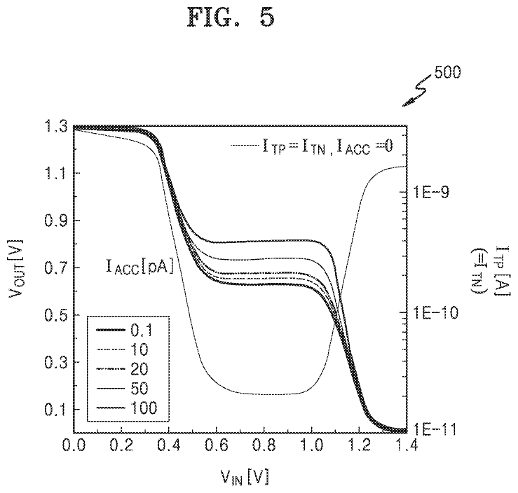

The pull-up device PU and the pull-down device PD may pass a constant current therethrough during turn-off. In other words, a through current I_{TP} of the pull-up device PU may be constant when the pull-up device PU is turned off, and a through current I_{TN} of the pull-down device PD may also be constant when the pull-down device PD is turned off. Furthermore, according to an embodiment of the disclosure, a threshold voltage of the pull-up device PU may be the same as a threshold voltage of the pull-down device PD. According to another embodiment of the disclosure, the threshold voltage of any one of the pull-up device PU and the pull-down device PD may be less than the threshold voltage of the other one. In an example, the threshold voltage of the pull-down device PD may be less than the threshold voltage of the pull-up device PU. Accordingly, when the input voltage V_{IN} gradually increases from the ground voltage GND to the positive supply voltage V_{DD}, the pull-down device PD may be turned on after the pull-up device PU is turned off. Accordingly, like the input voltage V_{IN}− the output voltage V_{OUT} characteristics of FIG. 5, both of the pull-up device PU and the pull-down device PD may be tuned off between about 0.6 V and about 1.1 V.

FIG. 5 is a graph showing an operation of an inverter included in a ternary memory cell in a TCAM device, according to various embodiments of the disclosure. A graph 500 of FIG. 5 shows an example of an operation of an inverter regarding the input voltage V_{IN}− the output voltage V_{OUT} characteristics and the input voltage V_{IN}− the through currents I_{TP} and I_{TN} characteristics. In the graph 500 of FIG. 5, the horizontal axis denotes the input voltage V_{IN}, the left vertical axis denotes the output voltage V_{OUT}, and the right vertical axis denotes the through currents I_{TP} and I_{TN} in a log scale. In the graph 500 of FIG. 5, the figures marked on the horizontal axis and the vertical axes are mere examples when the positive supply voltage V_{DD} is 1.4 V. and may vary according to the characteristics of a device.

Referring to FIG. 5, when there is no current I_{ACC} applied to an output end of the inverter, the through current I_{TF} of the pull-up device PU and the through current I_{TN} of the pull-down device PD may have the same amount, and the through currents I_{TP} and I_{TN} may be maintained constant at a low level between about 0.6 V and about 1.1 V. As a result, the output voltage V_{OUT} may be maintained substantially constant between about 0.6 V and about 1.1 V due to the through current I_{TP} of the pull-up device PU and the through current IN of the pull-down device PD. In other words, when the input voltage V_{IN} of an intermediate level, for example, about half V_{DD}/2 of the positive supply voltage V_{DD}, is provided, the inverter may output the output voltage V_{OUT} of an intermediate level, for example, about half V_{DD}/2 of the positive supply voltage V_{DD}. Accordingly, when the ground voltage GND, the intermediate voltage V_{DD}/2, and the positive supply voltage V_{DD}, which respectively correspond to 0/1/2 logic values, are input, the inverter may output the positive supply voltage V_{DD}, the intermediate voltage V_{DD}/2, and the ground voltage GND, which respectively correspond to 2/1/0 logic values. In the specification, the “intermediate voltage” is assumed to be the half V_{DD}/2 of the positive supply voltage V_{DD}, it would be understood that the intermediate voltage is a voltage of a certain level between the positive supply voltage V_{DD} and the ground voltage GND.

For SRAM including cross-coupled two inverters, a characteristic of not changing a value stored in a memory cell during a read-out operation, for example, a high read-out static noise margin (SNM), may be needed. Referring to FIG. 5, the inverter of FIG. 4 may provide a high read-out SNM even when the access current I_{ACC} increases, for example, the access current I_{ACC} is higher than the through currents I_{TP} and I_{TN}.

According to a device and method according to various embodiments of the disclosure, in a TCAM device based on a ternary memory cell, energy efficiency and area efficiency of a TCAM circuit may be increased through a T-CMOS-based TCAM circuit design. Furthermore, according to a device and method according to various embodiments of the disclosure, in a TCAM device based on a ternary memory cell, consumed power of the TCAM device may be reduced through a T-CMOS-based TCAM circuit design.

In the specific embodiments of the disclosure described above, constituent elements included in the disclosure are expressed in a singular or plural form according to the specific embodiments presented.

However, the singular or plural expression is appropriately selected for a particular situation presented for convenience of explanation, and thus the disclosure is not limited to the singular or plural constituent elements, and even if an element is expressed in a plural form, the element may be singular, or if an element is expressed in a singular form, the element may be plural.

The effects of the present disclosure are not limited to the above-described effects, and other various effects that are not described in the specification may be clearly understood from the following descriptions by one skilled in the art to which the present disclosure belongs.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A ternary content addressable memory (TCAM) cell in a TCAM device based on a ternary memory cell, the TCAM cell comprising:
a ternary memory cell configured to store ternary data; and
a comparison circuit configured to obtain a stored value stored in the ternary memory cell and a search value input via a search line of a search driver, identify a data match between the stored value and the search value, and output a result of the identification via a match line,
wherein the comparison circuit comprises:
a first transistor pair that receives an inverted stored value that is an inverted value of the stored value of the ternary memory cell and the search value; and
a second transistor pair that receives the stored value of the ternary memory cell and an inverted search value that is an inverted value of the search value, and
the first transistor pair and the second transistor pair are connected in parallel to each other.

2. The TCAM cell of claim 1, wherein the first transistor pair comprises a first transistor configured to receive the inverted stored value from a second node corresponding to the inverted stored value of ternary memory cell and a second transistor configured to receive a search value via a first search line of the search driver, the first transistor and the second transistor being connected in series to each other, and
the second transistor pair comprises a third transistor configured to receive the stored value from a first node corresponding to the stored value of the ternary memory cell and a fourth transistor configured to receive the inverted search value via a second search line of the search driver, the third transistor and the fourth transistor being connected in series to each other.

3. The TCAM cell of claim 2, wherein the first transistor is connected to the second node, the match line, and the second transistor,
the second transistor is connected to the first transistor and the first search line,
the third transistor is connected to the first node, the match line, and the fourth transistor, and
the fourth transistor is connected to the third transistor and the second search line.

4. The TCAM cell of claim 2, wherein the first transistor pair identifies whether the inverted stored value matches the search value,
the second transistor pair identifies whether the stored value matches the inverted search value, and
the comparison circuit is configured to output a signal indicating a result of a data match via the match line, on a basis of an identification result of the first transistor pair and an identification result of the second transistor pair.

5. The TCAM cell of claim 1, wherein the TCAM cell comprises one ternary memory cell and one comparison circuit.

6. The TCAM cell of claim 1, wherein a number of transistors included in the comparison circuit is four, and
a number of transistors included in the TCAM cell is ten.

7. A ternary content addressable memory (TCAM) device based on a ternary memory cell, the TCAM device comprising:
a search driver configured to provide a search word via a search line;
a TCAM cell array in which at least one TCAM cell is arranged, the at least one TCAM cell comprising a ternary memory cell and a comparison circuit, wherein the comparison circuit is configured to identify a data match between a stored value stored in the ternary memory cell and a search value of a search word input via a search line, and to output a result of the identification to an encoder via a match line; and
the encoder configured to output an address of the TCAM cell array having data matched with the search word, on a basis of a voltage provided via the match line connected to the TCAM cell array,
wherein the comparison circuit of the TCAM cell comprises:
a first transistor pair that receives an inverted stored value that is an inverted value of the stored value of the ternary memory cell and the search value; and
a second transistor pair that receives the stored value of the ternary memory cell and an inverted search value that is an inverted value of the search value, and
the first transistor pair and the second transistor pair are connected in parallel to each other.

8. The TCAM device of claim 7, wherein the first transistor pair comprises a first transistor configured to receive the inverted stored value from a second node corresponding to the inverted stored value of ternary memory cell and a second transistor configured to receive a search value via a first search line of the search driver, the first transistor and the second transistor being connected in series to each other, and
the second transistor pair comprises a third transistor configured to receive the stored value from a first node corresponding to the stored value of the ternary memory cell and a fourth transistor configured to receive the inverted search value via a second search line of the search driver, the third transistor and the fourth transistor being connected in series to each other.

9. The TCAM device of claim 7, wherein the TCAM cell comprises one ternary memory cell and one comparison circuit.
